(19) United States
(12) Patent Application Publication
(10) Pub. No.: US 2023/0170357 A1
(43) Pub. Date: Jun. 1, 2023

(54) ELECTRONIC DEVICE ALLOWING LIGHT TO PASS THROUGH, ELECTRONIC MODULE

(71) Applicant: InnoLux Corporation, Miao-Li County (TW)

(72) Inventors: Chandra LIUS, Miao-Li County (TW); Kuan-Feng LEE, Miao-Li County (TW)

(73) Assignee: InnoLux Corporation, Miao-Li County (TW)

(21) Appl. No.: 17/976,865

(22) Filed: Oct. 30, 2022

(30) Foreign Application Priority Data
Nov. 29, 2021 (CN) 202111435517.X

(51) Int. Cl. H01L 27/12; H01L 27/32

(52) U.S. Cl. CPC H01L 27/1251; H01L 27/3234; H01L 27/3262; H01L 27/3272; G06V 40/1318

(57) ABSTRACT

An electronic device allowing a light to pass through and an electronic module are disclosed. The electronic device includes a substrate, a silicon semiconductor disposed on the substrate, a first conductive layer disposed on the silicon semiconductor, an oxide semiconductor disposed on the substrate, and a second conductive layer disposed on the oxide semiconductor. One of the first conductive layer and the second conductive layer comprises a first opening through which the light is allowed to pass. The electronic module includes the electronic device and a fingerprint sensor or an image sensor disposed underneath the electronic device and configured to receive the light.

### BACKGROUND OF THE DISCLOSURE

### 1. Field of the Disclosure

The present disclosure relates to an electronic device and an electronic module. More particularly, the present disclosure relates to an electronic device allowing a light to pass through and an electronic module including the electronic device.

### 2. Description of the Prior Art

In order to fulfill the needs for lightweight and handy user experience, it is under extensive research in the industry to implement sensing functions into electronic modules, so that the operations of sensing signals, data input and displaying images may be performed on the same electronic modules. How to reduce the noise light received by the sensor to improve the sensing sensitivity is an important research topic in the field.

### SUMMARY OF THE DISCLOSURE

One objective of the present disclosure is to provide an electronic device allowing a light to pass through and an electronic module including the electronic device. The electronic device includes an opaque structure layer which is able to reduce the amount of noise lights passing through the electronic device and being received by a sensor disposed in the electronic module, so that the noise may be reduced and the sensing sensitivity may be improved.

Some embodiments of the present disclosure provide an electronic device capable of allowing a light to pass through, which includes a substrate, a silicon semiconductor disposed on the substrate, a first conductive layer disposed on the silicon semiconductor, an oxide semiconductor disposed on the substrate, and a second conductive layer disposed on the oxide semiconductor. One of the first conductive layer and the second conductive layer comprises a first opening through which the light is allowed to pass.

Some embodiments of the present disclosure provide an electronic module, which includes an electronic device capable of allowing a light to pass through, and a sensor disposed underneath the electronic device. The electronic device includes a substrate, a silicon semiconductor disposed on the substrate, a first conductive layer disposed on the silicon semiconductor, an oxide semiconductor disposed on the substrate, and a second conductive layer disposed on the oxide semiconductor. One of the first conductive layer and the second conductive layer comprises a first opening through which the light is allowed to pass. The sensor is configured to receive the light.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1A is a schematic cross-sectional view of an electronic device according to some embodiments of the present disclosure.

FIG. 1B shows schematic plan views of some examples of the opaque structure layer of the electronic device shown in FIG. 1A.

FIG. 2 is a schematic cross-sectional view of an electronic device according to some embodiments of the present disclosure.

FIG. 3 is a schematic cross-sectional view of an electronic device according to some embodiments of the present disclosure.

FIG. 4 is a schematic cross-sectional view of an electronic device according to some embodiments of the present disclosure.

FIG. 5 is a schematic cross-sectional view of an electronic device according to some embodiments of the present disclosure.

FIG. 6A is a schematic cross-sectional view of an electronic device according to some embodiments of the present disclosure.

FIG. 6B shows schematic plan views of some examples of the opaque structure layer of the electronic device shown in FIG. 6A.

FIG. 7 is a schematic cross-sectional view of an electronic device according to some embodiments of the present disclosure.

FIG. 8A is a schematic cross-sectional view of an electronic device according to some embodiments of the present disclosure.

FIG. 8B shows a schematic plan view of an example of the opaque structure layer of the electronic device shown in FIG. 8A.

FIG. 9 is a schematic cross-sectional view of an electronic device according to some embodiments of the present disclosure.

FIG. 10 is a schematic cross-sectional view of an electronic device according to some embodiments of the present disclosure.

FIG. 11 is a schematic cross-sectional view of an electronic device according to some embodiments of the present disclosure.

FIG. 12 is a schematic cross-sectional view of an electronic device according to some embodiments of the present disclosure.

FIG. 13 is a schematic cross-sectional view of an electronic device according to some embodiments of the present disclosure.

FIG. 14 is a schematic cross-sectional view of an electronic device according to some embodiments of the present disclosure.

FIG. 15 is a schematic cross-sectional view of an electronic device according to some embodiments of the present disclosure.

FIG. 16 shows schematic plan views of the opaque structure layer layers of the electronic devices shown in FIG. 14 and FIG. 15.

FIG. 17 is a schematic cross-sectional view of an electronic device according to some embodiments of the present disclosure.

### DETAILED DESCRIPTION

The present disclosure may be understood by reference to the following detailed specification, taken in conjunction with the drawings as described below. It is noted that, for purposes of illustrative clarity and being easily understood by the readers, various drawings of this disclosure show a portion of the electronic device, and certain components in various drawings may not be drawn to scale. In addition, the number and dimension of each component shown in drawings are only illustrative and are not intended to limit the scope of the present disclosure. Other embodiments may be utilized and structural, logical, and electrical changes may be made without departing from the scope of the present disclosure.

Certain terms are used throughout the specification and following claims to refer to particular components. As one skilled in the art will understand, electronic equipment manufacturers may refer to a component by different names. This document does not intend to distinguish between components that differ in name but not function. In the following specification and in the claims, the terms “include”, “comprise” and “have” are used in an open-ended fashion, and thus should be interpreted to mean “include, but not limited to”.

It will be understood that when a component or layer is referred to as being “on” or “connected to” another component or layer, it may be directly on or directly connected to the other component or layer, or intervening components or layers may be presented. In contrast, when a component is referred to as being “directly on” or “directly connected to” another component or layer, there are no intervening components or layers presented.

Spatially relative terms, such as “above”, “on”, “beneath”, “below”, “under”, “left”, “right”, “before”, “front”, “after”, “behind” and the like, used in the following embodiments only refer to the directions in the drawings and are not intended to limit the present disclosure. It should be understood that the components in the drawings may be disposed in any kind of formation known by one skilled in the related art to describe the components in a certain way. Furthermore, when one layer is “on” another layer or a substrate, it can be “directly on” the another layer or the substrate, or the one layer is on the another layer or the substrate, or another layer may be sandwiched between the one layer and the another layer or the substrate. In addition, in this specification, relative expressions, such as “lower”, “bottom”, “upper” or “top”, may be used to describe the position of one component relative to another. It is understood that if the device in the figures is turned over, components described as “lower” would then be oriented to be “upper” components.

The terms “first”, “second”, “third” or the like may be used in the specification and following claims for the convenience of discriminating various components in the specification or claims. However, these terms are not used to limit these components and these components may be denominate in any convenient way. These terms do not indicate any order of the components, and do not represent any order of a component to another component or a sequence of the manufacturing steps. Furthermore, the claims may use terminology different from that used in the specification, and may be nominated as “first”, “second”, “third” or the like in accordance with the order in which the components are declared in the claim. For example, a “first component” in the specification may be nominated as a “second component” in the claims.

In the present disclosure, the length, width, thickness, height or area, or the distance or spacing between components may be obtained by an optical microscope (OM), a scanning electron microscope (SEM), thin film thickness and surface morphology analysis equipment (such asa-step), an ellipsometer thickness measuring equipment, or by any suitable method and equipment. According to some embodiments, a scanning electron microscope may be used to obtain a structural cross-sectional image of the device to be inspected for measuring the width, thickness, height or area of the components of the device, but is not limited thereto. In addition, a finite range of error is permitted between any two values or directions used for comparison.

As disclosed herein, the term “about” or “substantial” generally means within 10%, 5%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

It should be noted that the technical features in different embodiments described in the following description may be replaced, recombined, or mixed with one another to constitute another embodiment without departing from the spirit of the present disclosure.

The electronic device of the present disclosure may include, but is not limited to, a display device, a backlight device, an antenna device, a sensor, or a spliced device. The display device may include a non-self-light-emitting display device or a self-light-emitting display device. The antenna device may include a liquid crystal antenna device or a non-liquid crystal antenna device. The sensor may include a capacitance sensor, a light sensor, a heat sensor, or an ultrasound sensor, but is not limited thereto. The spliced device may include a spliced display device or a spliced antenna device, but is not limited thereto. It should be noted that the electronic device may be any combination of the aforementioned devices, but is not limited thereto. In some embodiments, the electronic device of the present disclosure may be a bendable or flexible electronic device. The electronic module of the present disclosure includes at least one of the above electronic devices. In some embodiments, the electronic module of the present disclosure may be applied in the fields of in-screen fingerprint recognition technology, in-screen camera technical, and in-screen light sensing technical, but is not limited thereto.

The electronic device of the present disclosure may include electronic components such as passive components and active components, such as capacitors, resistors, inductors, diodes, transistors, and/or sensors. Among them, the diodes may include light emitting diodes or photodiodes, wherein the light emission diodes may include organic light emitting diode (OLED), mini LED, micro LED, or quantum dot LED, but is not limited thereto.

The opaque structure layer of the electronic device of the present disclosure may be made of any material with a light transmittance less than 20%, such as a dielectric material or a conductive material. In some embodiments, the opaque structure layer may be integrally formed in an original material layer of the electronic device through the same manufacturing process and/or using the same photomasks. In other embodiments, the opaque structure layer may be formed in a material layer additionally added to the electronic device or using additional photomasks, but is not limited thereto.

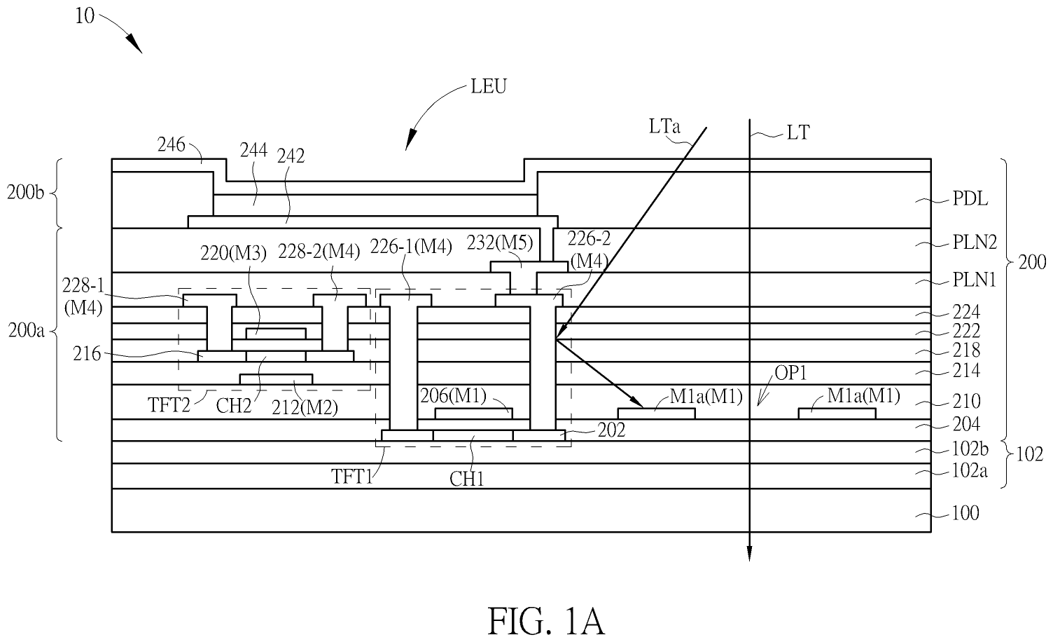

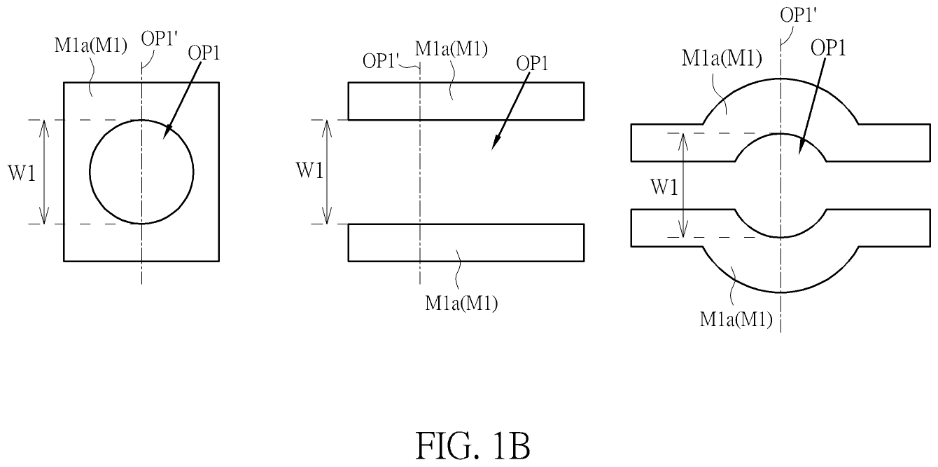

Please refer to FIG. 1A and FIG. 1B. FIG. 1A is a schematic cross-sectional view of an electronic device 10 according to some embodiments of the present disclosure. FIG. 1B shows schematic plan views of some examples of the opaque structure layer of the electronic device 10 in FIG. 1A. As shown in FIG. 1A, the electronic device 10 may include a substrate 100 and a display device layer 200 disposed on the substrate 100. In some embodiments, a buffer layer 102 may be disposed between the display device layer 200 and the substrate 100. In the embodiment shown in FIG. 1A, the upper side of the electronic device 10 includes an upper surface having the display device layer 200 and/or other electronic components formed thereon. The underside of the electronic device 10 includes an under surface of the substrate 100 (the surface of the substrate 100 opposite to the display device layer 200) and/or other electronic components disposed thereon. The electronic device 10 includes a region for a light LT to pass. A sensor (not shown) may be disposed on the underside of the electronic device 10. When the light LT (such as an ambient light or a reflected light) irradiating the upper side of the electronic device 10 passes through the display device layer 200, the buffer layer 102 and the upper surface of the substrate 100 to be received by the sensor, the sensor may convert the light LT into electric signal.

The substrate 100 may be a hard substrate or a flexible substrate. The material of the substrate 100 may include glass, ceramics, quartz, sapphire, polyimide (PI), polycarbonate (PC), polyethylene terephthalate (PET), or a combination thereof, but is not limited thereto. The buffer layer 102 may be a single-layer structure or a multi-layer structure. In some embodiments, the buffer layer 102 may include silicon nitride (SiNₓ), silicon oxide (SiOₓ), silicon oxynitride (SiON), or other suitable materials, but is not limited thereto. In the embodiment shown in FIG. 1A, the buffer layer 102 may include a first buffer layer 102a and a second buffer layer 102b. The materials of the first buffer layer 102a and the second buffer layer 102b may be the same or different.

The display device layer 200 may include a circuit layer 200a and a light emitting device layer 200b disposed on the circuit layer 200a. The circuit layer 200a may include a multi-layer structure, including driving circuitry for controlling operations of the light-emitting units LEU in the light-emitting device layer 200b. For example, the circuit layer 200a may include transistors, capacitors, data lines, scan lines, light-emitting control lines, power lines, ground potential lines, clock signal lines, fan out circuits and/or pixel electrodes, but are not limited thereto.

In detail, as shown in FIG. 1A, the circuit layer 200a may include a first semiconductor layer, a dielectric layer 204, a first conductive layer M1, a dielectric layer 210, a second conductive layer M2, a dielectric layer 214, a second semiconductor layer, a dielectric layer 218, a third conductive layer M3, a dielectric layer 222, a dielectric layer 224, a fourth conductive layer M4, a planarization layer PLN1, a fifth conductive layer M5, a planarization layer PLN2, or other suitable material layers, but are not limited thereto. The first semiconductor layer is one of the layers 202 and 216 shown in FIG. 1A, and the second semiconductor layer is the other one of the layers 202 and 216 shown in FIG. 1A. For example, when the first semiconductor layer is the layer 202, the second semiconductor layer is the layer 216. When the first semiconductor layer is the layer 216, the second semiconductor layer is the layer 202.

The dielectric layer 204, the dielectric layer 210, the dielectric layer 214, the dielectric layer 218, the dielectric layer 222, and the dielectric layer 224 may respectively have a single-layer structure or a multi-layer structure, and may include dielectric materials, such as silicon nitride (SiNₓ), silicon oxide (SiOₓ), silicon oxynitride (SiON), aluminum oxide (Al₂O₃), titanium oxide (TiO₂), tantalum oxide (Ta₂O₅), hafnium oxide (HfO₂), zirconium oxide (ZrO₂), or any combination of the above materials, but are not limited thereto. According to some embodiments of the present disclosure, the dielectric layer 204, the dielectric layer 214, the dielectric layer 218, and the dielectric layer 222 may respectively include silicon oxide, and the dielectric layer 210 and the dielectric layer 224 may respectively include silicon nitride. The planarization layer PLN1 and the planarization layer PLN2 may include organic dielectric materials such as acrylic resin, siloxane resin, epoxy resin, or other suitable dielectric materials, but are not limited thereto. The first conductive layer M1, the second conductive layer M2, the third conductive layer M3, the fourth conductive layer M4, and the fifth conductive layer M5 may respectively include a single layer or multiple layers. The materials of the above conductive layers may include metals such as aluminum (Al), copper (Cu), silver (Ag), chromium (Cr), titanium (Ti), molybdenum (Mo), nickel (Ni), moscovium (Mc), a composite layer or an alloy of the above metals, but is not limited thereto. According to some embodiments of the present disclosure, the first conductive layer M1, the second conductive layer M2, the third conductive layer M3, the fourth conductive layer M4, and the fifth conductive layer M5 may respectively include a multi-layer structure made of Mo/Al, Ti/Al, Mo/Cu, Ti/Cu, Mo/Al/Mo, Ti/Al/Ti, Mo/Cu/Mo, Ti/Cu/Ti. In some embodiments, the first semiconductor layer and the second semiconductor layer (layer 202 and layer 216) may comprise a single-layer or multi-layer structure. In some embodiments, the first semiconductor layer and the second semiconductor layer may respectively include a silicon-containing semiconductor material, an oxide semiconductor material, or a combination thereof, but is not limited thereto. In some embodiments, the materials of the first semiconductor layer and the second semiconductor layer may be the same or different.

The circuit layer 200a may include any suitable semiconductor devices. According to some embodiments of the present disclosure, the circuit layer 200a may include a silicon semiconductor thin film transistor TFT1 and an oxide semiconductor thin film transistor TFT2, but are not limited thereto. The silicon semiconductor thin film transistor TFT1 and the oxide semiconductor thin film transistor TFT2 may be disposed in different layers of the circuit layer 200a. In the embodiment shown in FIG. 1A, the silicon semiconductor thin film transistor TFT1 may be disposed between the second buffer layer 102b and the planarization layer PLN1. The silicon semiconductor thin film transistor TFT1 may be a top-gate-type transistor, comprising a silicon semiconductor 202, a channel region CH1 formed in the silicon semiconductor 202, a source electrode 226-1, a drain electrode 226-2, a portion of the dielectric layer 204, and a gate electrode 206. The material of the silicon semiconductor 202 may include amorphous silicon, low temperature polysilicon (LTPS) or single crystal silicon, but is not limited thereto. The gate electrode 206 is located on the channel region CH1, and may be formed by patterning the first conductive layer M1. The dielectric layer 204 is located between the gate electrode 206 and the silicon semiconductor 202 to serve as a gate insulating layer. The source electrode 226-1 and the drain electrode 226-2 of the silicon semiconductor thin film transistor TFT1 are located at two opposite sides of the channel region CH1 and may be formed by patterning the fourth conductive layer M4. In some embodiments, the silicon semiconductor thin film transistor TFT1 may be, for example, a bottom-gate type transistor, a double-gate type transistor, or other suitable types of transistors according to design needs.

The oxide semiconductor thin film transistor TFT2 may be disposed between the dielectric layer 210 and the planarization layer PLN1. The oxide semiconductor thin film transistor TFT2 may be a double-gate type transistor, comprising an oxide semiconductor 216, a channel region CH2 formed in the oxide semiconductor 216, a source electrode 228-1, a drain electrode 228-2, a portion of the dielectric layer 214, a portion of the dielectric layer 218, a bottom gate electrode 212, and a top gate electrode 220. The oxide semiconductor 216 may include a metal oxide material, such as indium gallium zinc oxide (IGZO), indium gallium tin oxide (IGTO), or indium gallium zinc tin oxide (IGTZO), but is not limited thereto. The bottom gate electrode 212 may be disposed under the oxide semiconductor 216 and formed by patterning the second conductive layer M2. The top gate 220 may be disposed over the oxide semiconductor 216 and formed by patterning the third conductive layer M3. The dielectric layer 214 is located between the bottom gate electrode 212 and the oxide semiconductor 216 to serve as a gate insulating layer for the bottom gate electrode 212. The dielectric layer 218 is located between the top gate electrode 220 and the oxide semiconductor 216 to serve as a gate insulating layer for the top gate electrode 220. The source electrode 228-1 and the drain electrode 228-2 of the oxide semiconductor thin film transistor TFT2 are located at two opposite sides of the channel region CH2, and may be formed by patterning the fourth conductive layer M4. In some embodiments, the oxide semiconductor thin film transistor TFT2 may be, for example, a bottom-gate type transistor, a top-gate type transistor, or other suitable types of transistors according to design needs.

The light-emitting device layer 200b may include a plurality of light-emitting units LEU (only one is shown in the drawings) and a pixel defining layer PDL for separating each of light-emitting devices LEU. The light-emitting units LEU may respectively include an organic light emitting diode (OLED), a mini LED, a micro LED, or a quantum dot LED, but is not limited thereto. According to an embodiment of the present disclosure, the light-emitting unit LEU shown in FIG. 1A may be an OLED, including an anode 242, a cathode 246, and a light emitting film 244 disposed between the anode 242 and the cathode 246. The anode 242 and the cathode 246 respectively include a conductive metal material, a transparent conductive material, or any suitable conductive material. The transparent conductive material for forming the anode 242 and the cathode 246 may include indium tin oxide (ITO), indium zinc oxide (IGZO), or aluminum zinc oxide (AZO), but is not limited thereto. The light-emitting film 244 may include an organic light-emitting material or an inorganic light-emitting material, but is not limited thereto. The light-emitting unit LEU shown in FIG. 1A has the anode 242 disposed under the light-emitting film 244 and electrically connected to the drain electrode 226-2 of the silicon semiconductor thin film transistor TFT1 through the conductive structure 232, which may be made by patterning the fifth conductive layer M5. The cathode 246 of the light-emitting unit LEU is disposed on the light-emitting film 244. In some embodiments, the arrangement of the anode 242 and the cathode 246 of the light emitting unit LEU may be interchanged according to design needs. In some embodiments, the cathode 246 may be electrically connected to a ground potential line (not shown). The pixel defining layer PDL may include an organic dielectric material, an inorganic dielectric material, or any suitable dielectric material, but is not limited thereto.

The electronic device 10 of the present disclosure includes an opaque structure layer formed in the circuit layer 200a or between the circuit layer 200a and the substrate 100. The opaque structure layer includes an opening, wherein most undesired noise lights outside the opening (such as the light LTa) are blocked by the opaque structure layer, and a desired portion of lights (such as the light LT) is allowed to pass through the opening to be received by the sensor (not shown) under the substrate 100. In this way, the sensing noise may be reduced and sensing accuracy may be improved. The opaque structure layer of the present disclosure may be made of any material with a light transmittance less than 20%. In some embodiments, the opaque structure layer may be formed by patterning at least one of the conductive layers of the circuit layer 200a, and may be integrally formed with the driving circuitry of the circuit layer 200a to simplify the manufacturing process and obtain a smaller thickness of the electronic device 10. In some embodiments, the opaque structure layer may be formed by patterning at least one of the first conductive layer M1, the second conductive layer M2, the third conductive layer M3, the fourth conductive layer M4, and the fifth conductive layer M5, but is not limited thereto.

For example, as shown in FIG. 1A, the electronic device 10 includes an opaque structure layer M1a including an opening OP1. The opaque structure layer M1a and the opening OP1 are formed by patterning the first conductive layer M1. In some embodiments, the opaque structure layer M1a and the gate electrode 206 of the silicon semiconductor thin film transistor TFT1 may be formed concurrently through the same manufacturing process and/or by the same photomask, and may include the same conductive material (that is, the material of the first conductive layer M1). The opening OP1 of the opaque structure layer M1a allows the light LT to pass through to be received by a sensor (not shown), wherein the sensor may be disposed on the underside of the electronic device 10, or disposed in the electronic device 10 and below the opening OP1. The light LTa is blocked by the opaque structure layer M1a around the opening OP1 and not be received by the sensor (not shown). In some embodiments, the light LTa is referred to as a noise light to the sensor.

The patterns and shapes of the opaque structure layer M1a and the opening OP1 may be adjusted according to design needs. In some embodiments, as shown in the left portion of FIG. 1B, the opening OP1 of the opaque structure layer M1a may be a closed opening, such as a pinhole, completely surrounded by a patterned portion of the first conductive layer M1. The width W1 of the opening OP1 may be the maximum width of the pinhole. For example, when the pinhole is substantially a circular hole, the width W1 is obtained approximately along the measuring line OP1′ through the center point of the pinhole. In some embodiments, as shown in the middle portion of FIG. 1B, the opening OP1 of the opaque structure layer M1a may be an open opening defined by two patterned portions of the first conductive layer M1 that extend in parallel along the same direction. The width W1 of the opening OP1 as shown in the middle portion of FIG. 1B may be obtained along the measuring line OP1′ which is through the largest space between the two patterned portions of the first conductive layer M1 (the width W1 is the maximum distance between the two patterned portions of the first conductive layer M1). In some embodiments, as shown in the right portion of FIG. 1B, the opening OP1 of the opaque structure layer M1a may be an open opening defined by two curved segments of the patterned portions of the first conductive layer M1. The width W1 of the opening OP1 as shown in the right portion of FIG. 1B may be obtained along the measuring line OP1′ which is through the largest space between the two patterned portions of the first conductive layer M1 (the width W1 is the maximum distance between the two patterned portions of the first conductive layer M1). The shapes of the opaque structure layer M1a and the opening OP1 illustrated in FIG. 1B are only examples, and the present disclosure is not limited thereto. In some embodiments, the opening OP1 of the opaque structure layer M1a may be an open opening defined by two patterned portions of the first conductive layer M1, wherein the two patterned portions of the first conductive layer M1 may include segments not parallel to each other. Any plan view shape of the opaque structure layer which is able to block passage of noise light is included in the scope of the present disclosure.

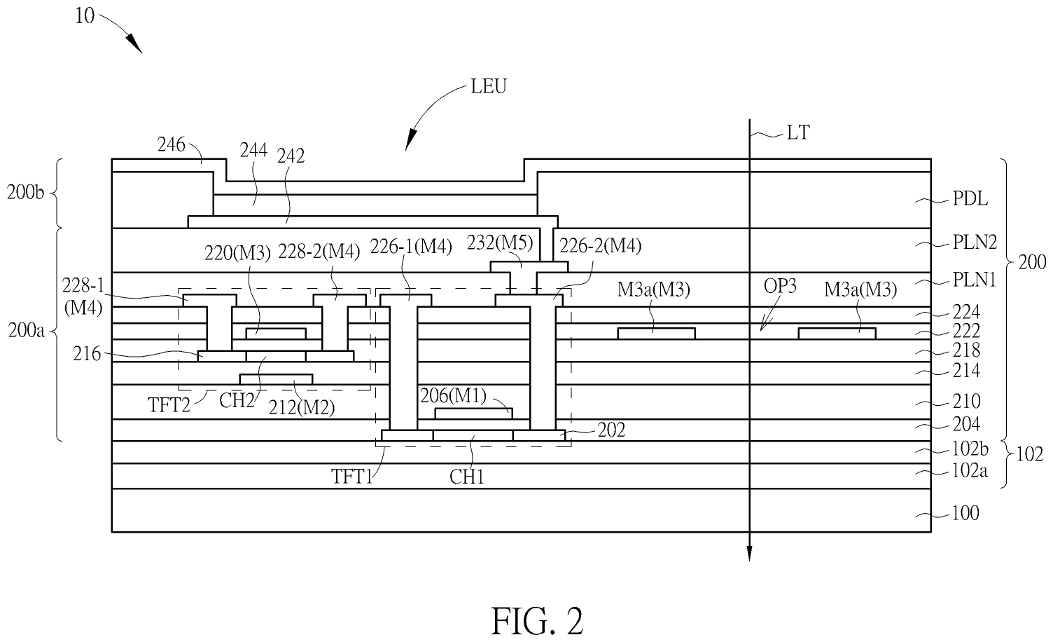

Please refer to FIG. 2, which is a schematic cross-sectional view of an electronic device 10 according to some embodiments of the present disclosure. Same reference numbers are used to annotate the same components in FIG. 2 and FIG. 1A. Some descriptions regarding the same components will be omitted for the sake of brevity. A difference between FIG. 2 and FIG. 1A is that, the opaque structure layer M3a and the opening OP3 of the electronic device 10 shown in FIG. 2 is formed by patterning the third conductive layer M3. In some embodiments, the opaque structure layer M3a and the top gate electrode 220 of the oxide semiconductor thin film transistor TFT2 may be formed concurrently through the same manufacturing process and/or by the same photomask, and may include the same conductive material (that is, the material of the third conductive layer M3). The opening OP3 of the opaque structure layer M3a allows the light LT to pass through to be received by a sensor (not shown), wherein the sensor may be disposed on the underside of the electronic device 10, or disposed in the electronic device 10 and below the opening OP3. Most lights outside the opening OP3 (like the light LTa outside the opening OP1) are blocked by the opaque structure layer M3a around the opening OP3 and not be received by the sensor (not shown). In some embodiments, the lights outside the opening OP3 are considered as noise lights to the sensor. The plan view shape of the opening OP3 may be referred to FIG. 1B, and will not be described again for the sake of brevity.

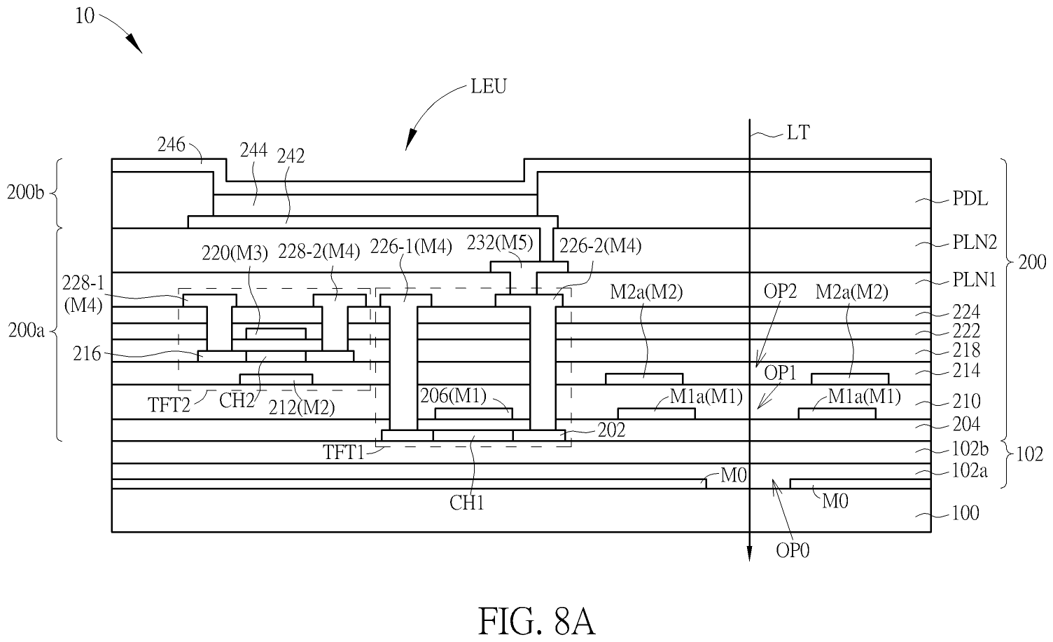

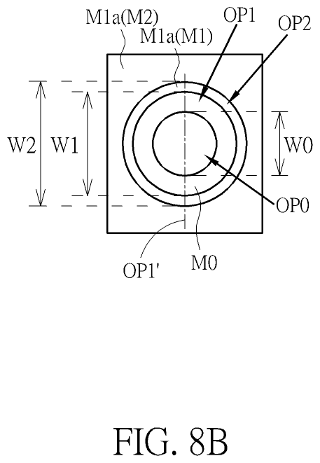

In some embodiments, the electronic device 10 shown in FIG. 2 may further include another opaque structure layer and another opening, such as the opaque structure layer M2a and the opening OP2 formed by patterning the second conductive layer M2 as shown in FIG. 8A. The opaque structure layer M2a and the bottom gate electrode 212 of the oxide semiconductor thin film transistor TFT2 may be formed concurrently through the same manufacturing process and/or by the same photomask, and may include the same conductive material (that is, the material of the second conductive layer M2). The opening OP2 of the opaque structure layer M2a allows the light LT to pass through to be received by a sensor (not shown) disposed on the underside of the electronic device 10 or disposed in the electronic device 10 and below the opening OP2. Most of the lights outside the opening OP2 are blocked by the opaque structure layer M2a around the opening OP2 and not be received by the sensor (not shown). The plan view shape of the opening OP2 may be referred to FIG. 1B, and will not be described again for the sake of brevity. In some embodiments, the opening OP2 and the opening OP3 are at least partially overlapped with each other in a direction vertical to the substrate 100, allowing the light LT to pass through and be received by a sensor (not shown) disposed on the underside of the electronic device 10 or disposed in the electronic device 10 and below the opening OP2. Most of the lights outside the outside the opening OP3 and the opening OP2 are blocked by the opaque structure layer M3a and/or the opaque structure layer M2a, and are not be received by the sensor (not shown). By having the opening OP3 and the opening OP2 in different conductive layers (that is, in different horizontal levels in the circuit layer 200a), the amount of the noise light received by the sensor may be further reduced.

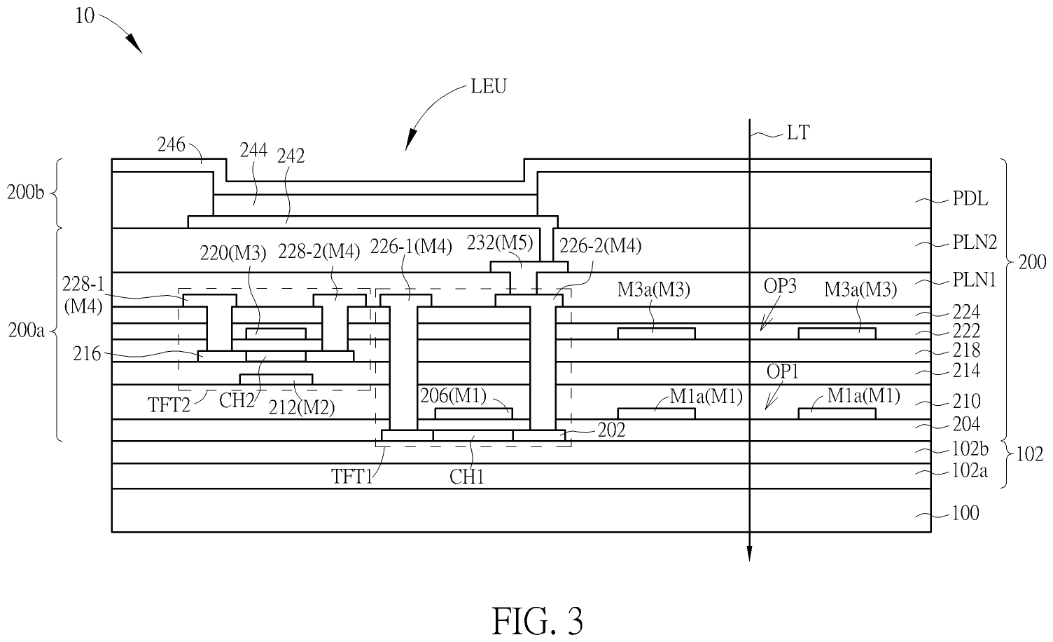

Please refer to FIG. 3, which is a schematic cross-sectional view of an electronic device 10 according to some embodiments of the present disclosure. Same reference numbers are used to annotate the same components in FIG. 3 and FIG. 1A and FIG. 2. Some descriptions regarding the same components will be omitted for the sake of brevity. One feature of the electronic device 10 shown in FIG. 3 is that, it has the opaque structure layer M1a, the opening OP1, the opaque structure layer M3a and the opening OP3. In some embodiments, the opening OP1 and the opening OP3 are both closed openings, such as pinholes. In some embodiments, the opening OP1 and the opening OP3 are both open openings. In some embodiments, one of the opening OP1 and the opening OP3 is a closed opening, and the other one of the opening OP1 and the opening OP3 is an open opening. The widths of the opening OP1 and the opening OP3 may be adjusted according to design needs, and may be the same or different. In some embodiments, the opening OP3 and the opening OP1 are at least partially overlapped with each other in a direction vertical to the substrate 100, allowing the light LT to pass through and be received by a sensor (not shown) disposed on the underside of the electronic device 10 or disposed in the electronic device 10 and below the opening OP1. By having the opening OP3 and the opening OP1 in different conductive layers (that is, in different horizontal levels in the circuit layer 200a), the amount of the noise light received by the sensor may be further reduced.

In some embodiments, the electronic device 10 shown in FIG. 3 may further include the opaque structure layer M2a and the opening OP2 formed by patterning the second conductive layer M2 as shown in FIG. 8A. The opaque structure layer M2a and the bottom gate electrode 212 of the oxide semiconductor thin film transistor TFT2 may be formed concurrently through the same manufacturing process and/or by the same photomask, and may include the same conductive material (that is, the material of the second conductive layer M2). The opening OP2 of the opaque structure layer M2a allows the light LT to pass through and be received by a sensor (not shown) disposed on the underside of the electronic device 10 or disposed in the electronic device 10 and below the opening OP1. Most of the lights outside the opening OP2 are blocked by the opaque structure layer M2a around the opening OP2 and not be received by the sensor (not shown). The plan view shape of the opening OP2 may be referred to FIG. 1B, and will not be described again for the sake of brevity. In some embodiments, the opening OP2 and the opening OP1 are at least partially overlapped with each other in a direction vertical to the substrate 100, allowing the light LT to pass through and be received by a sensor (not shown) disposed on the underside of the electronic device 10 or disposed in the electronic device 10 and below the opening OP1. The opening OP2 and the opening OP1 formed in different conductive layers (that is, in different horizontal levels in the circuit layer 200a) may further reduce the amount of the noise light received by the sensor. In some embodiments, the opening OP3, the opening OP2, and the opening OP1 are at least partially overlapped with each other in a direction vertical to the substrate 100, allowing the light LT to pass through and be received by a sensor (not shown) disposed on the underside of the electronic device 10 or disposed in the electronic device 10 and below the opening OP1. The opening OP3, the opening OP2, and the opening OP1 formed in different conductive layers (that is, in different horizontal levels in the circuit layer 200a) may further reduce the amount of the noise light received by the sensor.

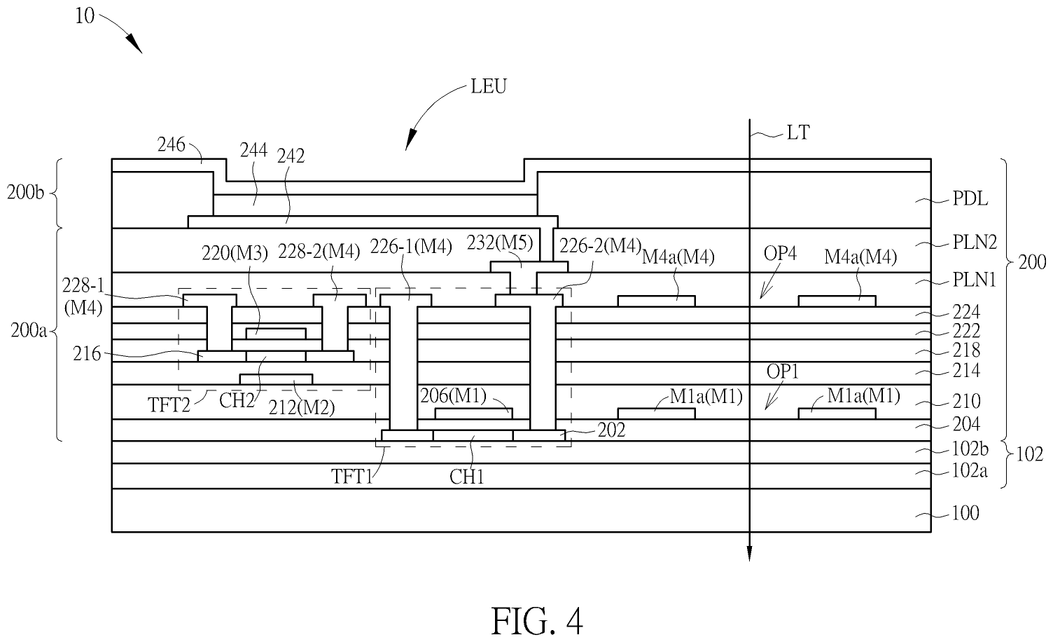

Please refer to FIG. 4, which is a schematic cross-sectional view of an electronic device 10 according to some embodiments of the present disclosure. Same reference numbers are used to annotate the same components in FIG. 4 and FIG. 1A. Some descriptions regarding the same components will be omitted for the sake of brevity. One feature of the electronic device 10 shown in FIG. 4 is that, it has the opaque structure layer M1a, the opening OP1, the opaque structure layer M4a and the opening OP4. In some embodiments, the opaque structure layer M4a, the source electrode 226-1 and the drain electrode 226-2 of the silicon semiconductor thin film transistor TFT1, and the source electrode 228-1 and the drain electrode 228-2 of the oxide semiconductor thin film transistor TFT2 are formed concurrently through the same manufacturing process and/or by the same photomask, and may include the same conductive material (that is, the material of the fourth conductive layer M4). The plan view shapes of the opening OP1 and the opening OP4 may be respectively referred to FIG. 1B, and will not be described again for the sake of brevity. In some embodiments, the opening OP1 and the opening OP4 are both closed openings, such as pinholes. In some embodiments, the opening OP1 and the opening OP4 are both open openings. In some embodiments, one of the opening OP1 and the opening OP4 is a closed opening, and the other one of the opening OP1 and the opening OP4 is an open opening. The widths of the opening OP1 and the opening OP4 may be adjusted according to design needs, and may be the same or different. In some embodiments, the opening OP4 and the opening OP1 are at least partially overlapped with each other in a direction vertical to the substrate 100, allowing the light LT to pass through and be received by a sensor (not shown) disposed on the underside of the electronic device 10 or disposed in the electronic device 10 and below the opening OP1. By having the opening OP4 and the opening OP1 in different conductive layers (that is, in different horizontal levels in the circuit layer 200a), the amount of the noise light received by the sensor may be further reduced.

In some embodiments, the electronic device 10 shown in FIG. 4 may further include the opaque structure layer M2a and the opening OP2 formed by patterning the second conductive layer M2 as shown in FIG. 8A. The opaque structure layer M2a and the bottom gate electrode 212 of the oxide semiconductor thin film transistor TFT2 may be formed concurrently through the same manufacturing process and/or by the same photomask, and may include the same conductive material (that is, the material of the second conductive layer M2). The opening OP2 of the opaque structure layer M2a allows the light LT to pass through and be received by a sensor (not shown) disposed on the underside of the electronic device 10 or disposed in the electronic device 10 and below the opening OP1. Most of the lights outside the opening OP2 are blocked by the opaque structure layer M2a around the opening OP2 and not be received by the sensor (not shown). The plan view shape of the opening OP2 may be referred to FIG. 1B, and will not be described again for the sake of brevity. In some embodiments, the opening OP2 and the opening OP4 are at least partially overlapped with each other in a direction vertical to the substrate 100, allowing the light LT to pass through and be received by a sensor (not shown) disposed on the underside of the electronic device 10 or disposed in the electronic device 10 and below the opening OP1. The opening OP4 and the opening OP2 formed in different conductive layers (that is, in different horizontal levels in the circuit layer 200a) may further reduce the amount of the noise light received by the sensor. In some embodiments, the opening OP4, the opening OP2, and the opening OP1 are at least partially overlapped with each other in a direction vertical to the substrate 100, allowing the light LT to pass through and be received by a sensor (not shown) disposed on the underside of the electronic device 10 or disposed in the electronic device 10 and below the opening OP1. The opening OP4, the opening OP2, and the opening OP1 formed in different conductive layers (that is, in different horizontal levels in the circuit layer 200a) may further reduce the amount of the noise light received by the sensor.

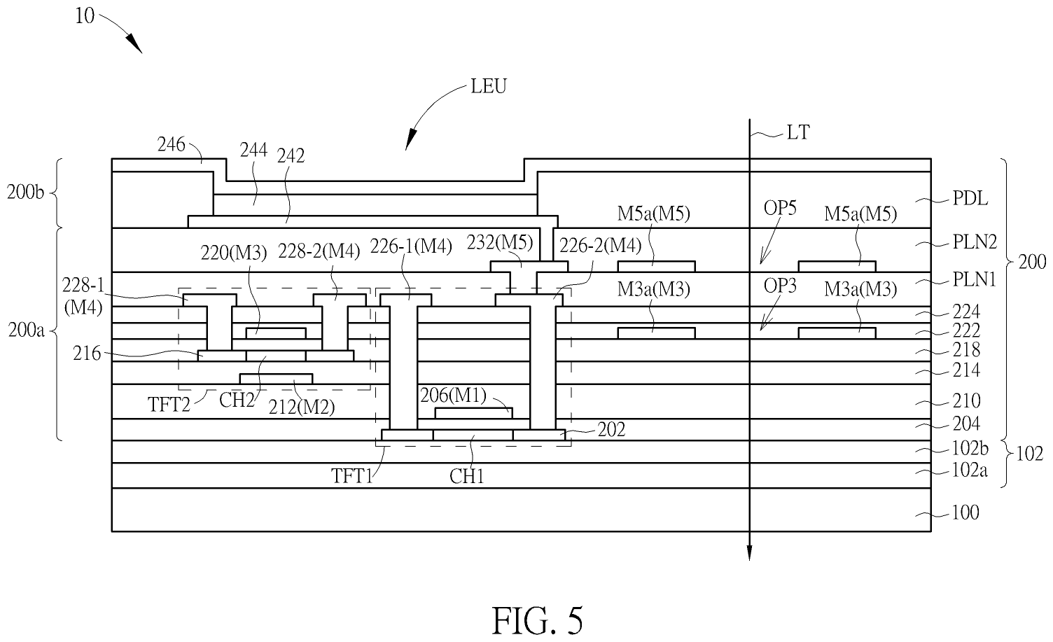

Please refer to FIG. 5, which is a schematic cross-sectional view of an electronic device 10 according to some embodiments of the present disclosure. Same reference numbers are used to annotate the same components in FIG. 5 and FIG. 2. Some descriptions regarding the same components will be omitted for the sake of brevity. One feature of the electronic device 10 shown in FIG. 5 is that, it has the opaque structure layer M3a, the opening OP3, the opaque structure layer M5a and the opening OP5. In some embodiments, the opening OP5 and the opening OP3 are at least partially overlapped with each other in a direction vertical to the substrate 100, allowing the light LT to pass through and be received by a sensor (not shown) disposed on the underside of the electronic device 10 or disposed in the electronic device 10 and below the opening OP3. The opaque structure layer M5a and the conductive structure 232 may be formed concurrently through the same manufacturing process and/or by the same photomask, and may include the same conductive material (that is, the material of the fifth conductive layer M5). The plan view shapes of the opening OP3 and the opening OP5 may be respectively referred to FIG. 1B, and will not be described again for the sake of brevity. In some embodiments, the opening OP3 and the opening OP5 are both closed openings, such as pinholes. In some embodiments, the opening OP3 and the opening OP5 are both open openings. In some embodiments, one of the opening OP3 and the opening OP5 is a closed opening, and the other one of the opening OP3 and the opening OP5 is an open opening. The widths of the opening OP3 and the opening OP5 may be adjusted according to design needs, and may be the same or different. The opening OP3 and the opening OP5 formed in different conductive layers (that is, in different horizontal levels in the circuit layer 200a) may further reduce the amount of the noise light received by the sensor.

In some embodiments, the electronic device 10 shown in FIG. 5 may further include the opaque structure layer M2a and the opening OP2 formed by patterning the second conductive layer M2 as shown in FIG. 8A. The opaque structure layer M2a and the bottom gate electrode 212 of the oxide semiconductor thin film transistor TFT2 may be formed concurrently through the same manufacturing process and/or by the same photomask, and may include the same conductive material (that is, the material of the second conductive layer M2). The opening OP2 of the opaque structure layer M2a allows the light LT to pass through and be received by a sensor (not shown) disposed on the underside of the electronic device 10 or disposed in the electronic device 10 and below the opening OP2. Most of the lights outside the opening OP2 are blocked by the opaque structure layer M2a around the opening OP2 and not be received by the sensor (not shown). The plan view shape of the opening OP2 may be referred to FIG. 1B, and will not be described again for the sake of brevity. In some embodiments, the opening OP5 and the opening OP2 are at least partially overlapped with each other in a direction vertical to the substrate 100, allowing the light LT to pass through and be received by a sensor (not shown) disposed on the underside of the electronic device 10 or disposed in the electronic device 10 and below the opening OP2. The opening OP5 and the opening OP2 formed in different conductive layers (that is, in different horizontal levels in the circuit layer 200a) may further reduce the amount of the noise light received by the sensor. In some embodiments, the opening OP5, the opening OP3, and the opening OP2 are at least partially overlapped with each other in a direction vertical to the substrate 100, allowing the light LT to pass through and be received by a sensor (not shown) disposed on the underside of the electronic device 10 or disposed in the electronic device 10 and below the opening OP2. The opening OP5, the opening OP3, and the opening OP2 formed in different conductive layers (that is, in different horizontal levels in the circuit layer 200a) may further reduce the amount of the noise light received by the sensor.

In some embodiments, the electronic device 10 shown in FIG. 5 may further include the opaque structure layer M1a and the opening OP1 as shown in FIG. 1A. The opening OP5 and the opening OP1 are at least partially overlapped with each other in a direction vertical to the substrate 100, allowing the light LT to pass through and be received by a sensor (not shown) disposed on the underside of the electronic device 10 or disposed in the electronic device 10 and below the opening OP1. The opening OP5 and the opening OP1 formed in different conductive layers (that is, in different horizontal levels in the circuit layer 200a) may further reduce the amount of the noise light received by the sensor. In some embodiments, the opening OP5, the opening OP3, and the opening OP1 are at least partially overlapped with each other in a direction vertical to the substrate 100, allowing the light LT to pass through and be received by a sensor (not shown) disposed on the underside of the electronic device 10 or disposed in the electronic device 10 and below the opening OP1. The opening OP5, the opening OP3 and the opening OP1 formed in different conductive layers (that is, in different horizontal levels in the circuit layer 200a) may further reduce the amount of the noise light received by the sensor.

In some embodiments, the electronic device 10 shown in FIG. 5 may further include the opening OP2 as shown in FIG. 8A and the opening OP1 as shown in FIG. 1A, wherein the opening OP5, the opening OP3, the opening OP2 and the opening OP1 are at least partially overlapped with each other in a direction vertical to the substrate 100, allowing the light LT to pass through and be received by a sensor (not shown) disposed on the underside of the electronic device 10 or disposed in the electronic device 10 and below the opening OP1. The opening OP5, the opening OP3, the opening OP2, and the opening OP1 formed in different conductive layers (that is, in different horizontal levels in the circuit layer 200a) may further reduce the amount of the noise light received by the sensor.

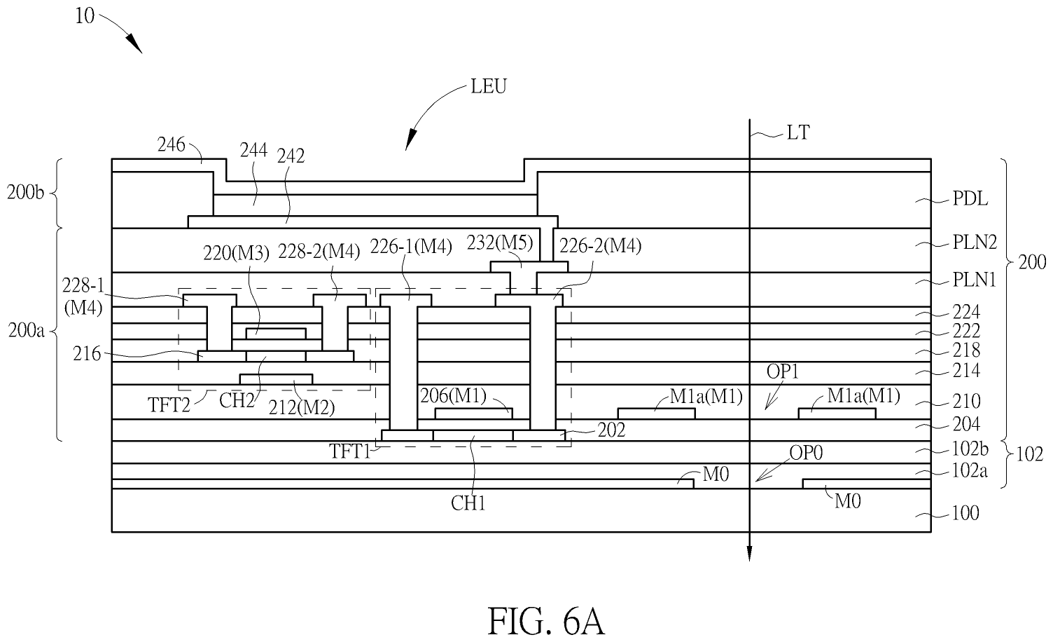

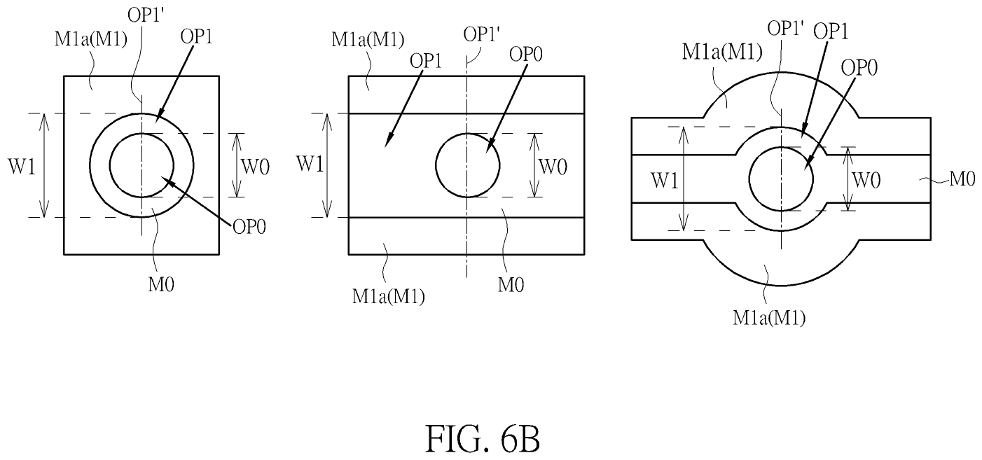

Please refer to FIG. 6A and FIG. 6B. FIG. 6A is a schematic cross-sectional view of an electronic device 10 according to some embodiments of the present disclosure. FIG. 6B shows schematic plan views of some examples of the opaque structure layer of the electronic device 10 in FIG. 6A. Same reference numbers are used to annotate the same components in FIG. 6A and FIG. 1A. Some descriptions regarding the same components will be omitted for the sake of brevity. A difference between FIG. 6A and FIG. 1A is that, the electronic device 10 shown in FIG. 6A further includes an opaque structure layer M0 having an opening OP0 disposed on the substrate 100, or between the substrate 100 and the silicon semiconductor 202, or below the electronic elements or material layers of the circuit layer 200a (such as the silicon semiconductor 202 and the oxide semiconductor 216). The opaque structure layer M0 may be made of a dielectric material or a conductive material with a light transmittance less than 20%. The opaque structure layer M0 may have a single-layer structure or a multi-layer structure. According to some embodiments of the present disclosure, the opaque structure layer M0 includes a conductive material, such as a metal material including aluminum (Al), copper (Cu), silver (Ag), chromium (Cr), titanium (Ti), molybdenum (Mo), nickel (Ni), moscovium (Mc), a composite layer or an alloy of the above metals, but is not limited thereto. The opening OP0 and the opening OP1 defined in the first conductive layer M1 are at least partially overlapped with each other in a direction vertical to the substrate 100, wherein the opening OP0 is closer to the substrate 100. The light LT may pass through the opening OP1 and the opening OP0 and be received by a sensor (not shown) disposed on the underside of the electronic device 10.

The patterns of the opening OP1 and the opening OP0 may be adjusted according to design need, and may respectively be a closed opening or an open opening. For example, as shown in the left portion of FIG. 6B, the opening OP0 and the opening OP1 are both pinholes and completely surrounded by the opaque structure layer M0 or the opaque structure layer M1. As shown in the middle portion of FIG. 6B, the opening OP0 is a pinhole, and the opening OP1 is an open opening defined by two patterned portions of the first conductive layer M1 that extend in parallel along a same direction. As shown in the right portion of FIG. 6B, the opening OP0 is a pinhole, and the opening OP1 is an open opening defined by two curved segments of the patterned portions of the first conductive layer M1. The shapes of the opaque structure layer M1a, the opening OP1, the opaque structure layer M0 and the opening OP0 shown in FIG. 6B are only examples, and the present disclosure is not limited thereto. In some embodiments, the opening OP1 of the opaque structure layer M1a may be an open opening defined by two patterned portions of the first conductive layer M1, wherein the two patterned portions of the first conductive layer M1 may include segments not parallel to each other. Any plan view shape of the opaque structure layer which is able to block passage of noise light is included in the scope of the present disclosure.

The widths of the opening OP0 and the opening OP1 may be adjusted according to design needs. For example, the width W0 of the opening OP0 is smaller than the width W1 of the opening OP1, so that a portion of the opaque structure layer M0 may be revealed from the opening OP1 in the plan views as shown in FIG. 6B. In the embodiment shown in the left portion of FIG. 6B, the opening OP0 and opening OP1 are arranged to form concentric circles, wherein the width W0 of the opening OP0 and the width W1 of the opening OP1 are obtained approximately along the measuring line OP1′ concurrently through the center points of the opening OP0 and the opening OP1. In the embodiment shown in the middle portion of FIG. 6B, the width W0 of the opening OP0 and the width W1 of the opening OP1 are obtained approximately along the measuring line OP1′ that is through the center point of the opening OP0. In some embodiments, the opening OP0 shown in FIG. 6B may be replaced by one of the openings OP0 to OP5, and the opening OP1 shown in FIG. 6B may be replaced by another one of the openings OP0 to OP5. In other words, the overlapping plan views in FIG. 6B may be formed by any two of the openings OP0 (located below the semiconductor layers as shown in FIG. 6A) to OP5, but is not limited thereto.

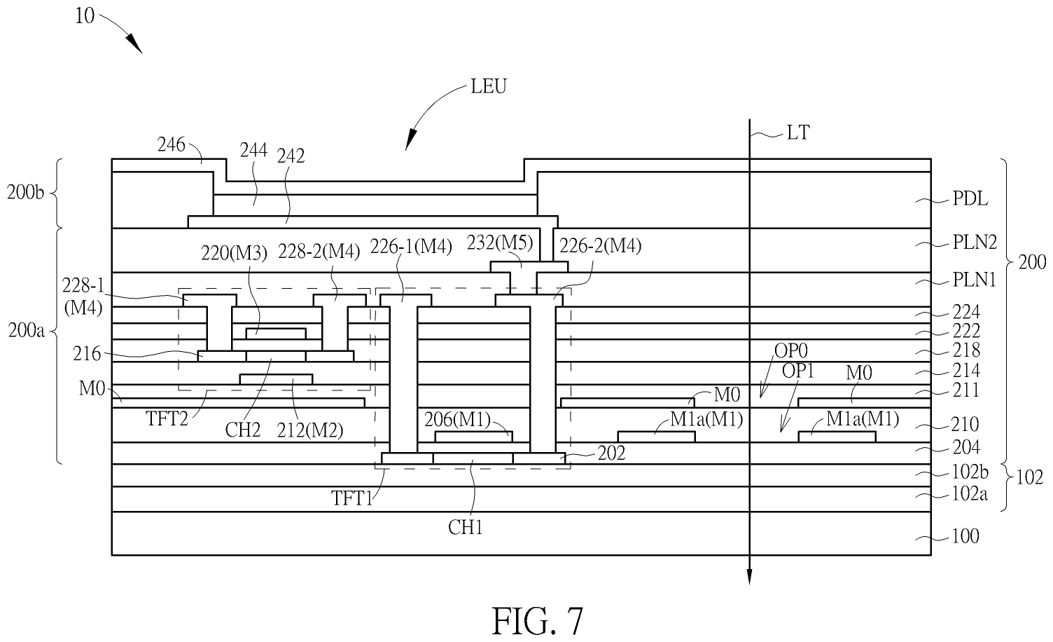

Please refer to FIG. 7, which is a schematic cross-sectional view of an electronic device 10 according to some embodiments of the present disclosure. Same reference numbers are used to annotate the same components in FIG. 7 and FIG. 1A to FIG. 6A. Some descriptions regarding the same components will be omitted for the sake of brevity. A difference between FIG. 7 and FIG. 6A is the locations of the opaque structure layer M0 and the opening OP0. As shown in FIG. 7, the electronic device 10 includes the opaque structure layer M0, the opening OP0, the opaque structure layer M1, and the opening OP1, wherein the opaque structure layer M0 and the opening OP0 are located in the circuit layer 200a, or above one of the semiconductor layers, such as between the planarization layer PLN2 and the silicon semiconductor 202, or on the dielectric layer 10 and above the silicon semiconductor 202. The opening OP0 of the opaque structure layer M0 shown in FIG. 7 may be a closed opening (such as a pinhole), at least partially overlapped with the opening OP1 in a direction vertical to the substrate 100, and is closer to the substrate 100 than the opening OP1. The plan view shapes of the opening OP0 and the opening OP1 of the electronic device 10 in FIG. 7 may be referred to FIG. 6B, and will not be described again for the sake of brevity. The overlapping plan views in FIG. 6B may be formed by any two of the openings OP0 (located above one of the semiconductor layers as shown in FIGS. 7) to OP5, but is not limited thereto.

Please refer to FIG. 8A and FIG. 8B. FIG. 8A is a schematic cross-sectional view of an electronic device 10 according to some embodiments of the present disclosure. FIG. 8B shows a schematic plan view of an example of the opaque structure layer of the electronic device 10 shown in FIG. 8A. Same reference numbers are used to annotate the same components in FIG. 8A and FIG. 6A. Some descriptions regarding the same components will be omitted for the sake of brevity. A difference between FIG. 8A and FIG. 6A is that, the electronic device 10 shown in FIG. 8A further includes an opaque structure layer M2a having an opening OP2 formed concurrently with the bottom gate electrode 212 of the oxide semiconductor thin film transistor TFT2 through the same manufacturing process and/or by the same photomask, and may include the same conductive material (that is, the material of the second conductive layer M2). The opening OP2, the opening OP1 and the opening OP0 of the electronic device 10 shown in FIG. 8A are at least partially with each other in a direction vertical to the substrate 100, allowing the light LT to pass through and be received by a sensor (not shown) disposed on the underside of the electronic device 10. The plan view shapes of the opening OP0, the opening OP1, and the opening OP2 of the electronic device 10 shown in FIG. 8A may be referred to FIG. 1B and FIG. 6B. In some embodiments, as shown in FIG. 8B, the opening OP0, the opening OP1, and the opening OP2 are closed openings such as pinholes, and the width W0 of the opening OP0 that is closest to the substrate 100 is smaller than the width W1 of the opening OP1 that is farther away from the substrate 100 than the opening OP0, and the width W1 of the opening OP1 is smaller than the width W2 of the opening OP2 that is farther away from the substrate 100 than the opening OP1, wherein the width W0, the width W1, and the width W2 are respectively obtained approximately along measuring lines OP1′ through the center point of the pinholes. As a result, in the plan view as shown in FIG. 8B a portion of the opaque structure layer M0 may be revealed from the opening OP1, and a portion of the opaque structure layer M1 (the first conductive layer M1) may be revealed from the opening OP2. In some embodiments, as shown in FIG. 8B, the opening OP0, the opening OP1, and the opening OP2 may are arranged to form concentric circles, and the measuring lines OP1′ are overlapped. In some embodiments, the opening OP0 in FIG. 8B may be replaced by one of the openings OP0 to OP5, the opening OP1 in FIG. 8B may be replaced by another one of the openings OP0 to OP5, and the opening OP2 in FIG. 8B may be replaced by still another one of the openings OP0 to OP5. In other words, the overlapping plan views in FIG. 8B may be formed by any three of the openings OP0 (located below the semiconductor layers as shown in FIG. 8A) to OP5, but is not limited thereto.

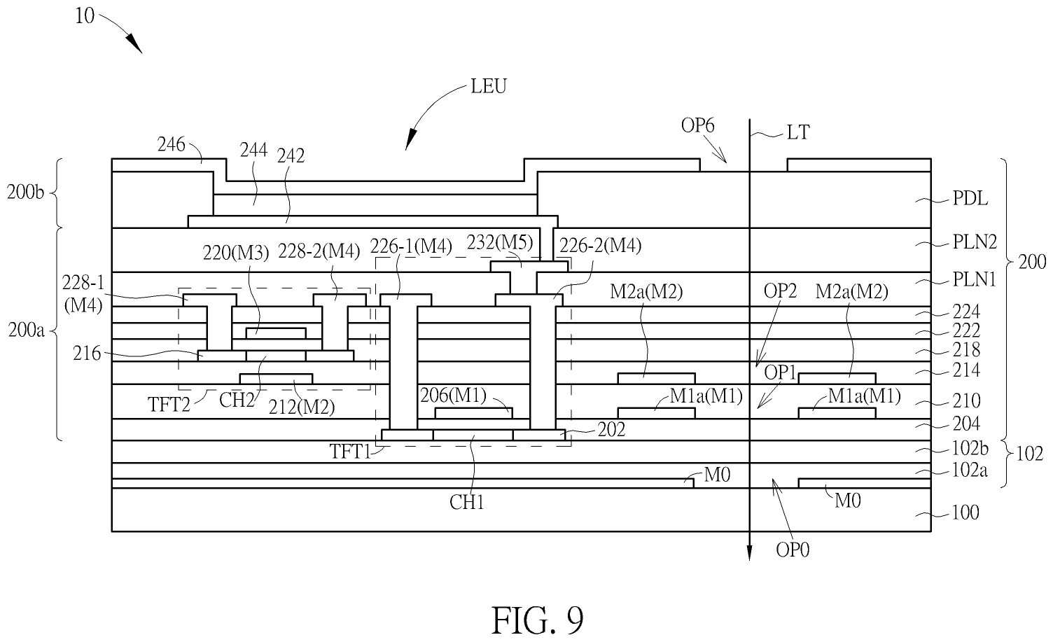

Please refer to FIG. 9, which is a schematic cross-sectional view of an electronic device 10 according to some embodiments of the present disclosure. Same reference numbers are used to annotate the same components in FIG. 9 and FIG. 1A to FIG. 8. Some descriptions regarding the same components will be omitted for the sake of brevity. A difference between FIG. 9 and FIG. 8A is that, the cathode 246 of the electronic device 10 in FIG. 9 includes an opening OP6 which is formed by patterning the cathode 246. The opening OP6 is at least partially overlapped with at least one of the openings OP0 to OP5 in a direction vertical to the substrate 100. For example, as shown in FIG. 9, the opening OP6, the opening OP2, the opening OP1 and the opening OP0 are at least partially overlapped with each other along the direction vertical to the substrate 100. By forming the opening OP6 to allow light LT to pass through the cathode 246, problems of low signal intensity due to low light transmittance of the cathode 246 (between 50% and 60%) may be improved.

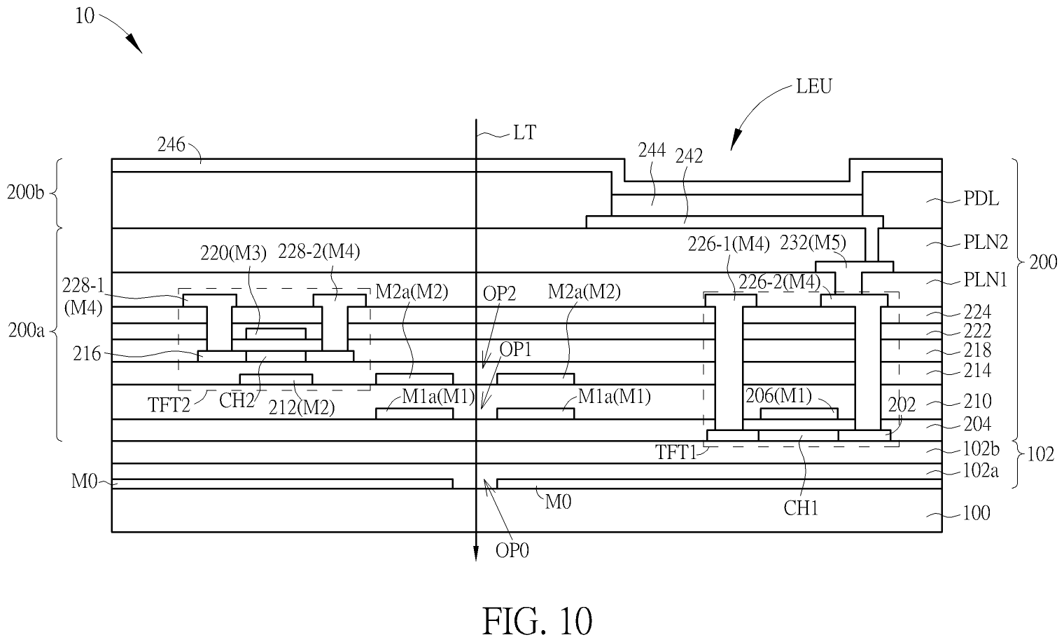

Please refer to FIG. 10, which is a schematic cross-sectional view of an electronic device 10 according to some embodiments of the present disclosure. Same reference numbers are used to annotate the same components in FIG. 10 and FIG. 1A to FIG. 9, and will not be illustrated in detail for the sake of brevity. The electronic device 10 may have at least one of the openings OP0 to OP6 formed in any suitable region on the substrate 100 according to design needs, such as the region between the silicon semiconductor thin film transistor TFT1 and the oxide semiconductor thin film transistor TFT2. For example, as shown in FIG. 10, the electronic device 10 includes the opening OP0, the opening OP1 and the opening OP2 formed in the region between the silicon semiconductor thin film transistor TFT1 and the oxide semiconductor thin film transistor TFT2, which are at least partially overlapped along the direction vertical to the substrate 100 to allow light LT to pass through and be received by a sensor (not shown) disposed on the underside of the electronic device 10 or below the opening OP0. The electronic device 10 in FIG. 10 is an example, and should not be taken as a limitation to the present disclosure.

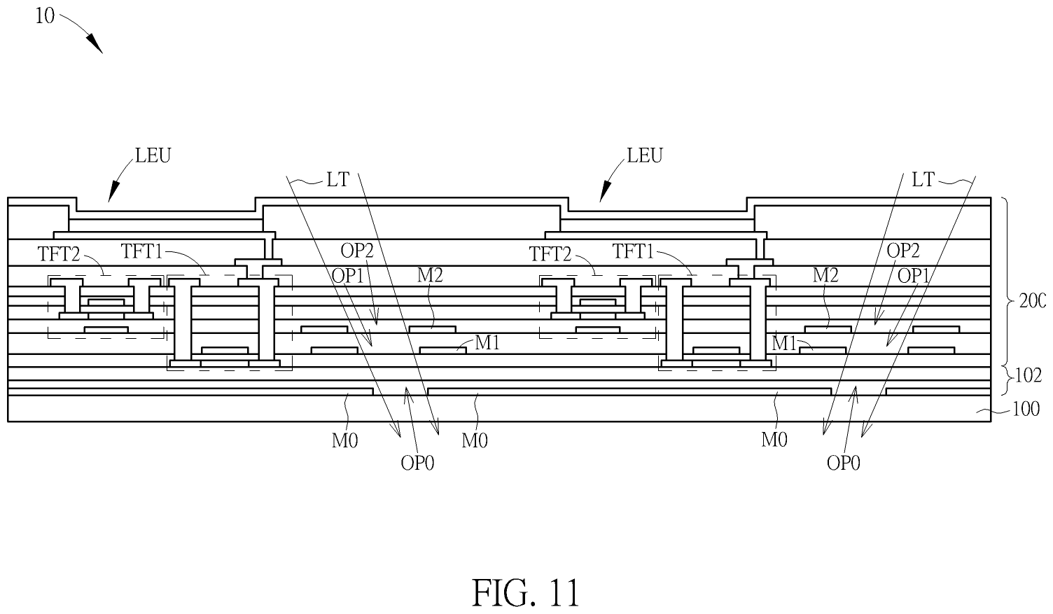

Please refer to FIG. 11, which is a schematic cross-sectional view of an electronic device 10 according to some embodiments of the present disclosure. Same reference numbers are used to annotate the same components in FIG. 11 and FIG. 1A to FIG. 10, and will not be illustrated in detail for the sake of brevity. In some embodiments, at least two of the openings OP0 to OP6 are arranged on the substrate 100 and gradually shift toward a certain direction as the increasing distances from the substrate 100 to be offset along the vertical direction. The offset arrangement design of openings is able to guide irradiating lights LT from different incident angles to pass through the electronic device 10 to be received by the sensors (not shown) below the electronic device 10. The offset-arranged openings may be formed in at least one region of the electronic device 10. In some embodiments, the offset-arranged openings may be formed in two regions of the electronic device 10, and the offset directions of the openings in the two regions may be the same or different. For example, as shown in FIG. 11, two sets of openings (for example, the openings OP0, OP1, and OP2) are formed in different regions of the electronic device 10 to allow the lights LT to pass. The openings are gradually shift as the increasing distances from the substrate 100 to be offset along the vertical direction, and the offset directions of the openings may be different to guide irradiating lights LT from different incident angles to pass through the electronic device 10 and be received by different sensors (not shown) below the electronic device 10.

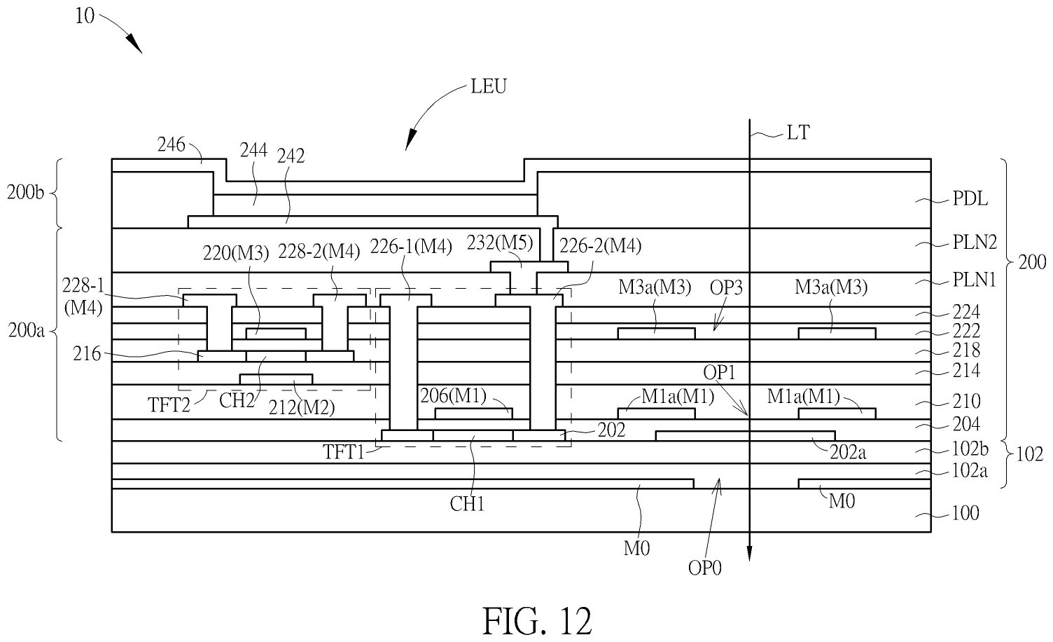

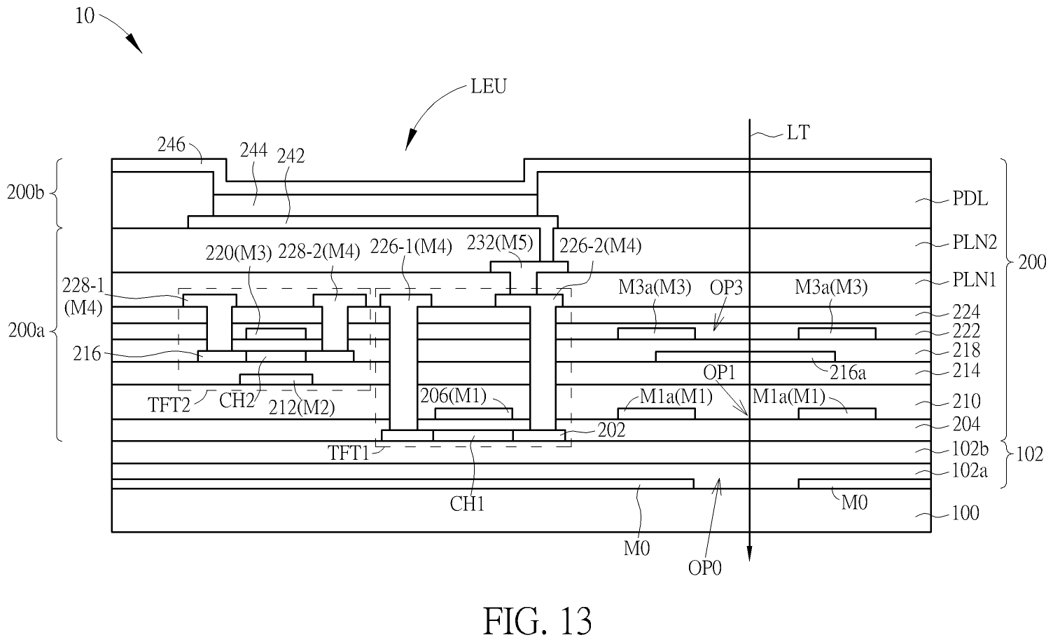

Please refer to FIG. 12 and FIG. 13, which are schematic cross-sectional views of the electronic devices 10 according to some embodiments of the present disclosure. Same reference numbers are used to annotate the same components in FIG. 12, FIG. 13 and FIG. 1A to FIG. 11, and will not be illustrated in detail for the sake of brevity. In some embodiments, a light filter layer may be disposed in the passage of the light LT through the electronic devices 10 to allow the light LT of a specific wavelength range to pass through and be received by a sensor (not shown) below the electronic device 10. The light filter layer may be formed in an original material layer of the electronic device 10 through the same manufacturing process and/or using the same photomasks to form the components of the electronic device 10. In other embodiments, the light filter layer may be formed in a material layer additionally added to the electronic device 10 or using additional photomasks, but is not limited thereto.

For example, the electronic devices 10 shown in FIG. 12 may include a light filter layer 202a formed over the opening OP0. The light filter layer 202a may be formed concurrently with the silicon semiconductor 202 of the silicon semiconductor thin film transistor TFT1 through the same manufacturing process and/or using the same photomask. The light filter layer 202a may include the same material as the silicon semiconductor 202, such as amorphous silicon, low temperature polysilicon (LTPS) or single crystal silicon, but is not limited thereto. In some embodiments, the light filter layer 202a only allows lights in red and infrared (IR) wavelengths ranges to pass. The electronic devices 10 shown in FIG. 13 may include a light filter layer 216a formed over the opening OP1. The light filter layer 216a may be formed concurrently with the oxide semiconductor 216 of the oxide semiconductor thin film transistor TFT2 through the same manufacturing process and/or using the same photomask. The light filter layer 216a may include the same material as the oxide semiconductor 216, such as indium gallium zinc oxide (IGZO), indium gallium tin oxide (IGTO), or indium gallium zinc tin oxide (IGTZO), but is not limited thereto. In some embodiments, the light filter layer 216a may absorb lights in the blue wavelength range and allow lights in other wavelength ranges such as green, red and infrared wavelength ranges to pass.

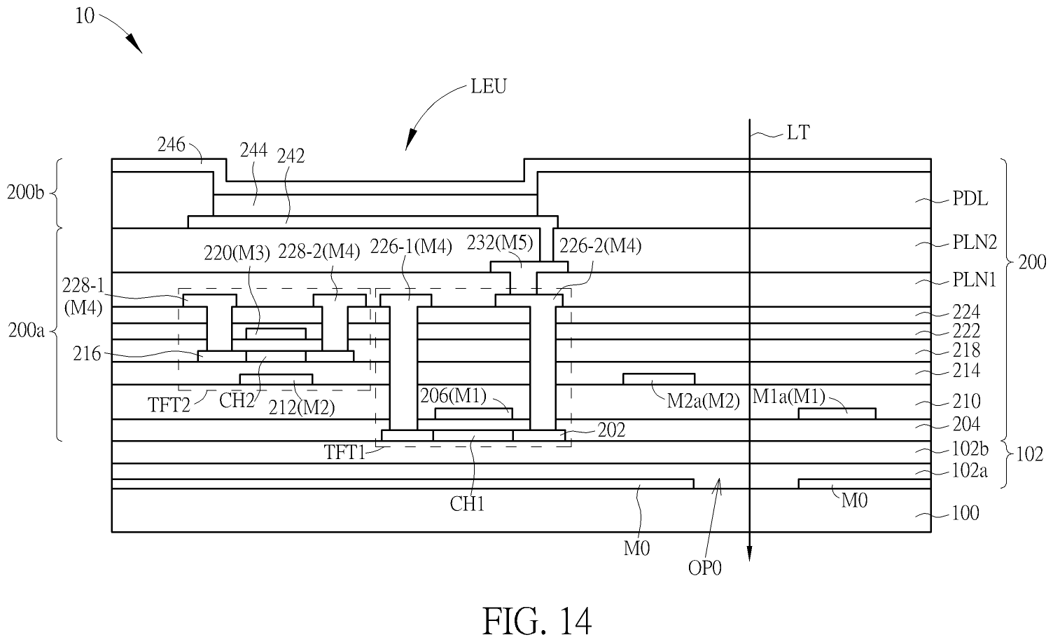

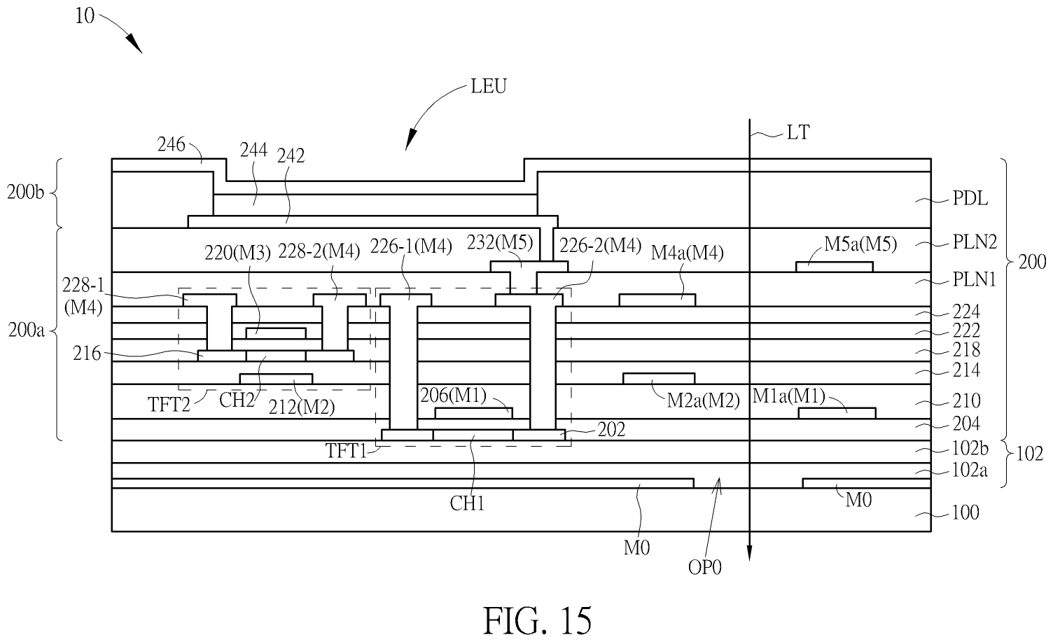

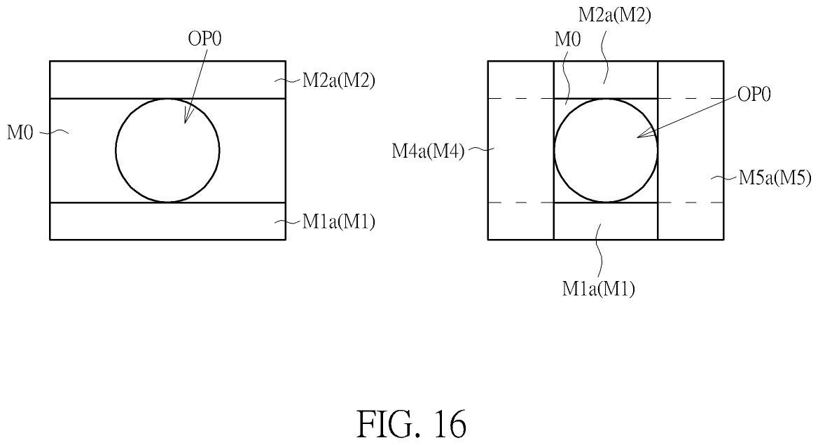

Please refer to FIG. 14, FIG. 15, and FIG. 16. FIG. 14 and FIG. 15 are schematic cross-sectional views of the electronic devices 10 according to some embodiments of the present disclosure. The left portion of FIG. 16 is a schematic plan view of the opaque structure layer of the electronic device of FIG. 14. The right portion of FIG. 16 is a schematic plan view of the opaque structure layer of the electronic device of FIG. 15. Same reference numbers are used to annotate the same components in FIG. 14, FIG. 15, FIG. 16 and FIG. 1A to FIG. 13, and will not be illustrated in detail for the sake of brevity. In some embodiments, at least one of the openings allowing lights to pass through may be formed by opaque structure layers in different layers. In some embodiments, two sides of opening may be formed by different layers of the opaque structure layers M0 to M5a. In other words, one of the opaque structure layers M0 to M5a may be used to define a side (such as the left side or the upper side) of the opening, and another one of the opaque structure layers M0 to M5a may be used to define another side (such as the right side or the lower side) of the opening. In this case, the opening is defined by any two of the opaque structure layers M0 to M5a. For example, as shown in FIG. 14 and the left portion of FIG. 16, the electronic device 10 includes an opaque structure layer M1a disposed above one side of the opening OP0, and an opaque structure layer M2a disposed above the other side of the opening OP0. The opaque structure layer M0, the opaque structure layer M1a, and the opaque structure layer M2a work together to block passage of noise lights from two sides of the opening OP0. In some embodiments, the surrounding of the opening may be formed by different layers of the opaque structure layers M0 to M5a. In other words, one of the opaque structure layers M0 to M5a may be used to define the upper side of the opening, another one of the opaque structure layers M0 to M5a may be used to define the lower side of the opening, still another one of the opaque structure layers M0 to M5a may be used to define the left side of the opening, and still another one of the opaque structure layers M0 to M5a may be used to define the right side of the opening. In this case, the opening is defined by any four of the opaque structure layers M0 to M5a. For example, as shown in FIG. 14 and the right portion of FIG. 16, the electronic device 10 includes an opaque structure layer M1a, an opaque structure layer M2a, an opaque structure layer M4a, and an opaque structure layer M5a respectively disposed above a side of the opening OP0, and collectively surround the opening OP0 in the plan view of the electronic device 10 to block passage of noise lights from all sides of the opening OP0. The opening formed by opaque structure layers in different layers may be used to replace at least one of the openings OP0 to OP6 as illustrated previously, but is not limited thereto. The plan view shapes of the opaque structure layers and the openings shown in FIG. 16 are only examples. Any design of the opaque structure layer which is able to block passage of noise light is included in the scope of the present disclosure.

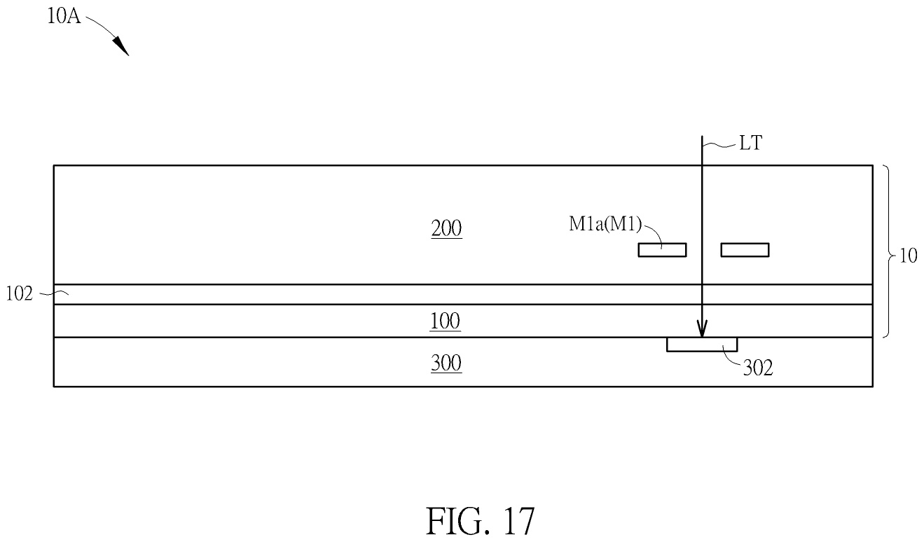

Please refer to FIG. 17, which is a schematic cross-sectional view of an electronic module 10A according to some embodiments of the present disclosure. The electronic module 10A includes the electronic device 10 described previously in the embodiments and a sensor 300 disposed under the electronic device 10. The light LT may pass through the electronic device 10 to be received by a sensing component 302 of the sensor 300. The sensing component 302 may convert the light LT into electric signal. In some embodiments, the sensor 300 may be a fingerprint sensor (FPS) or an image sensor (image sensor). The electronic device 10 may include opaque structure layers as detailed in previous embodiments to block passage of noise lights, so that the sensing noise may be reduced and sensing accuracy may be improved. It should be understood that the opaque structure layer M1a shown in FIG. 17 is an example to show where the opaque structure layers may be disposed, and are not intended to limit the scope of the present disclosure. In some embodiments, the sensor 300 may be full plane to completely overlap a display area of the electronic device 10. In some embodiments, the sensor 300 may not be a full plane, and overlaps a portion of the electronic device 10.

In conclusion, the electronic device provided by the present disclosure includes an opaque structure layer which is able to block the passage of noise lights and reduce the amount of noise lights being received by a sensor disposed under the electronic device or below the light passage opening, so that the noise may be reduced and the sensing sensitivity may be improved. Furthermore, the opaque structure layers may be formed by patterned portions of the original material layers of the electronic device, and may be integrally formed with other components of the electronic device through the same manufacturing process and/or using the same photomasks, so that the manufacturing process may be simplified and a smaller thickness of the electronic device may be achieved.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device capable of allowing a light to pass through, comprising:
a substrate;
a silicon semiconductor disposed on the substrate;
a first conductive layer disposed on the silicon semiconductor;
an oxide semiconductor disposed on the substrate; and
a second conductive layer disposed on the oxide semiconductor;
wherein one of the first conductive layer and the second conductive layer comprises a first opening through which the light is allowed to pass.

2. The electronic device according to claim 1, wherein the other one of the first conductive layer and the second conductive layer comprises a second opening which is at least partially overlapped with the first opening.

3. The electronic device according to claim 2, further comprising an opaque structure layer disposed on the substrate and having a third opening, wherein the third opening is at least partially overlapped with the first opening and the second opening.

4. The electronic device according to claim 1, wherein the first opening is a pinhole.

5. The electronic device according to claim 1, further comprising an opaque structure layer disposed on the substrate and having a third opening, wherein the third opening is at least partially overlapped with the first opening.

6. The electronic device according to claim 5, wherein the third opening is a pinhole.

7. The electronic device according to claim 5, wherein the silicon semiconductor is disposed on the opaque structure layer.

8. The electronic device according to claim 5, wherein the opaque structure layer is disposed between the silicon semiconductor and the oxide semiconductor.

9. The electronic device according to claim 5, wherein the third opening is closer to the substrate than the first opening and a width of the third opening is smaller than a width of the first opening.

10. The electronic device according to claim 5, further comprising a third conductive layer disposed on the silicon semiconductor, wherein the third conductive layer comprises a fourth opening, and the first opening, the third opening and the fourth opening are at least partially overlapped with each other.

11. The electronic device according to claim 10, wherein the third conductive layer is a single-layered structure.

12. The electronic device according to claim 5, further comprising a third conductive layer disposed on the oxide semiconductor, wherein the third conductive layer comprises a fourth opening, and the first opening, the third opening and the fourth opening are at least partially overlapped with each other.

13. The electronic device according to claim 12, wherein the third conductive layer is a multi-layered structure.

14. The electronic device according to claim 1, wherein the second conductive layer is disposed on the first conductive layer.

15. The electronic device according to claim 1, wherein the first conductive layer is a single-layered structure.

16. The electronic device according to claim 1, wherein the second conductive layer is a multi-layered structure.

17. The electronic device according to claim 1, wherein the first conductive layer comprises a first gate electrode which is overlapped with the silicon semiconductor.

18. The electronic device according to claim 1, wherein the second conductive layer comprises a second gate electrode which is overlapped with the oxide semiconductor.

19. An electronic module, comprising:
the electronic device as claimed in claim 1; and
a sensor disposed underneath the electronic device and configured to receive the light.

20. The electronic module according to claim 19, wherein the sensor is a fingerprint sensor or an image sensor.
